(19) United States
(12) Patent Application Publication
(10) Pub. No.: US 2026/0291280 A1
(43) Pub. Date: Sep. 24, 2026

(54) MONITORING TRANSFORMERS OF POWER NETWORKS

(71) Applicant: Landis+Gyr AG, Cham (CH)

(72) Inventor: Monisha DAS, Cham (CH)

(21) Appl. No.: 19/168,618

(22) PCT Filed: Mar. 28, 2024
(86) PCT No.: PCT/EP2024/058481

§ 371 Date: Sep. 24, 2025

(30) Foreign Application Priority Data
Mar. 31, 2023 (GB) 2304832.5

(51) Int. Cl. H02J 13/18; G06N 3/08; H02J 13/10; H02J 13/12; H02J 103/35

(52) U.S. Cl. CPC H02J 13/18; G06N 3/08; H02J 13/10; H02J 13/12; H02J 2103/35

(57) ABSTRACT

A method of estimating historical apparent power over time of at least one transformer device in a power network in a geographic region, the method comprising: providing training data comprising: apparent power data of a plurality of transformer devices over time in one or more geographic regions, energy consumption data over time of the power network in the respective geographic regions, and ambient environmental temperature data over time of the respective geographic regions; initialising weights of an untrained neural network comprising an input layer, a plurality of hidden layers, and an output layer, and using the training data to iteratively update the weights to minimise a loss function to produce a trained neural network configured to output an estimated apparent power of a transformer device over a time period in a geographic region from input energy consumption data and input ambient environmental temperature data of said geographic region over said time period; and inputting energy consumption data and ambient environmental temperature data over a first time period in a geographic region into the trained neural network to estimate an apparent power over the first time period of at least one transformer device in the geographic region.

### TECHNICAL FIELD

The present disclosure is directed to the field of monitoring distribution transformers of power networks, particularly to estimating remaining service lifetimes of such transformers and estimating parameters for use in such estimating.

### BACKGROUND

A transformer is a static electrical machine that steps up and steps down voltages while transferring electrical energy from one circuit to another. It works on the principle of mutual inductance between the windings of a transformer for allowing the transfer of electrical energy between circuits. A distribution transformer is a type of transformer that provides the final voltage transformation in the electric power distribution system, stepping down the voltage used in the distribution lines to the level used by the customer. A distribution transformer is typically a three-phase unit with dual secondary windings which are centre-tapped to provide single- or three-phase service. The primary winding is connected to the distribution voltage, usually at a medium voltage level between 10 kV and 36 kV. The secondary winding is connected to the customer voltage, typically a low voltage level between 240V and 600V. The distribution transformer is a critical component in the electric power distribution system.

Distribution transformers can be further categorised on the type of electrical insulation and thermal cooling mechanism it uses. It can be a dry type or can be oil-immersed. The present disclosure is concerned with, oil-immersed transformers. These transformers typically include a tank, containing the transformer's metal core with coil windings, which is filled with oil. The oil removes heat from the transformer and ensures the dielectric strength of the insulation.

Thermal ageing and insulation degradation affects the transformer lifetime. A transformer's hot spot temperature is the spot in a winding of the transformer with the highest temperature, which can degrade the insulation material, leading to transformer breakdown. Thus, hotspot temperature is an important parameter when defining a transformer's thermal condition and overloading capability.

In practice, the hot-spot temperature of the transformer depends on the ambient temperature and the loading factor, which is expressed as the ratio of apparent power to the base load of the transformer. Measuring the hot-spot temperature of the transformer is crucial for the asset managers at the provider of the power network, such as a utility company. At a high level, transformer life depends generally on the service conditions within the environment in which the transformer is operating and by the reliability of the other components of the transformer. Non-exhaustive examples which may impact the life of the transformer include:
The type of insulation used (e.g. oil type and composition)·
The transformer operating temperature
The transformer loads
The oil and hotspot temperature.
The transformer's environment, such as moisture, dust, and ambient temperature.
The manufacturing quality of the insulation
The transformer's historical load

There are many challenges providers of power networks face while operating and managing the networks, one of the challenges being prioritising distribution transformer replacements.

For example, the introduction of nonlinear loads like rectifiers, discharge lighting or saturated electrical machines into power networks has caused an influx of non-sinusoidal waves of current and voltage harmonics in the power networks. The harmonics have started showing up in the past 30 years. A voltage harmonic or current harmonic frequency is an integer multiple of the fundamental frequency. Total harmonic distortion is the measurement of harmonics present in an electrical signal. It can be calculated using the ratio of the Root Mean Square (RMS) amplitude of higher harmonic frequencies to the RMS amplitude of fundamental frequency. When subjected to non-sinusoidal conditions due to harmonic distortion, the transformers designed for fundamental frequency pure sinusoidal supply result in increased iron, copper, and dielectric losses, causing an increase in temperature rise. The percentage rise of temperature above rated condition will depend on the increase in losses due to harmonic distortions. The increased temperature rise because of harmonics will cause faster deterioration of the insulation resulting in a reduction in life. The heat generated by these losses also impacts the oil quality in these transformers, thereby giving rise to the hotspot temperatures as discussed above. This can have huge repercussions on the accelerated ageing of a transformer, leading to early failures or replacement.

Whilst modern transformers can typically handle the detrimental effect of these losses. The transformers manufactured during the 1960s and earlier were not designed to anticipate the harmonic load. Increased use of nonlinear devices in today's network is responsible for faster degradation of insulation material in transformers. Indeed there is a worrying increased rate of failure of these older transformers which is due in part to an increase in harmonics in power networks.

To compound this problem, a large proportion power networks worldwide rely on distribution transformers installed in the 1950s to 1960s which were already coming to the end of life. Limited resources prevent providers from replacing all the needed transformers at once and it forces them to keep transformers operating beyond their rated service lifetime (i.e. the time a transformer manufacturer intended the transformer to be used while having an acceptably low risk of failure). For providers, it is essential to know the optimal time of replacement of an asset. If an asset is not replaced at the right time, it may cause shortcomings resulting in higher costs and customer complaints. On the other hand, replacing the assets too early is unsustainable and uneconomical. The opportunity to gain years of additional productivity and enhance the sustainability of such assets would be beneficial to providers of power networks. Thus, understanding the current state of transformers (i.e. how long of a service lifetime does a given transformer have left before it fails or the risk of failure becomes unacceptably high) enables the providers to prioritise their replacement and maintenance schedules cost-effectively, which helps providers manage their operational expenditure and capital expenditure costs significantly. Existing methods for determining the state of transformers are applied only sporadically in long time intervals, can be unsafe, and are not providing sufficient information to asset managers.

For example, one known method uses a process known as dissolved gas analysis (DGA). DGA provides detection of incipient fault conditions that may lead to the main failure modes of the transformer. Dissolved gas analysis is typically performed by taking a transformer oil sample manually and sending it to a laboratory. The sample is then injected into a gas chromatograph, separating the various dissolved gases, and identifying their concentrations. The results are then analyzed to determine whether any fault conditions are present. The gases present in transformer oil are formed by the decomposition of the transformer insulation. The most common gases found in transformer oil are ethane, ethylene, acetylene, hydrogen, methane, and other Greenhouse Gases (GHGs). These gases are formed by the decomposition of the cellulose insulation in the transformer. Transformer oil sample analysis provides valuable information for determining transformer health, based on which the DSOs can decide about further maintenance activities and scheduling transformer's replacement.

The gases in transformer oil can convey a great deal about the transformer's health. For example, high hydrogen gas concentrations can indicate a transformer with a high degree of electrical stress. High concentrations of methane and ethane can indicate a transformer with a high degree of thermal stress. Thermal stresses are caused by varying temperatures and the thermal coefficient of expansion of different materials. Thermal stresses can cause the insulation to crack, thereby reducing the dielectric strength of the insulation. Thermal stresses can also cause the insulation to swell and collapse, causing air pockets to form in the insulation and increasing the risk of an electrical fault. Electrical stresses are caused by the application of high voltages to the insulation. These stresses can cause the insulation to break down and allow electrical current to flow through the insulation.

However, a problem with the DGA approach is that it is an intrusive method that requires a maintenance engineer to actively open a transformer housing to sample the oil, exposing themselves and the public to an open transformer. It also cannot be performed continuously or on a daily, or weekly basis at all transformers in a power network given the cost that doing so would incur resulting from having to hire hundreds of engineers to conduct the manual sampling in a power network, and resulting from the logistics of testing a large number of samples on a regular basis.

As a result, many power network providers simply avoid or minimise the frequency performing regular monitoring and maintenance of distribution transformers. In some extreme cases, distribution transformers are not monitored at all and whenever maintenance is performed it may consist of cleaning up the transformer station, a visual inspection, and occasionally performing DGA to check the oil quality. However, the consequence of transformer failure can be catastrophic.

Hence, the asset managers of power network providers would benefit from being able to monitor the transformer's health remotely and regularly. Further, power network providers are expected to ensure high availability and rapid recovery after an outage.

In order to attempt to harmonise how transformers are managed and maintained globally, the Institute of Electric and Electronic Engineers (IEEE) has developed a number of standards by which transformer lifetimes are determined. A relevant standard to the present disclosure is that which is used to calculate loss of life. Loss of life is a metric indicating how much of a transformer's intended lifetime has already been used up, which in turn indicates how long the transformer's service lifetime has remaining before it needs to be replaced.

Specifically, loss of life is defined as a reduction of the transformer's insulation's ability to perform its function of providing electrical separation. It is characterized by an increase in the insulation's dielectric losses, which results in a corresponding increase in the transformer's operating temperature. Loss of life in mineral oil-immersed transformers has been formulated in the ANSI/IEEEC57.91 and IEC-354.91 standards.

According to IEEE Standard ANSI/IEEEC57.91, the normal life of transformers is 50 years. This life corresponds to continuous operation at the designed hot spot temperature of 110° C. In contrast, the IEC standard IEC-354.91 has not defined a total life, but it is usually equal to 30 years depending on the ageing rate determined by the hot spot temperature. The loss of life calculation is given by the IEEE loading guide, which assumes that insulation deterioration can be modelled as a per-unit quantity for a reference temperature of 110° C. The equation for accelerated ageing FAA is given by the equation 1, which is dependent on the hotspot temperature of the transformer:

$${F}_{AA} = {e}^{[ \frac{15000}{{θ}_{HR} + 273 ° C .} - \frac{15000}{{θ}_{H} + 273 ° C .} ]} \qquad Eq . 1$$

Where:
θ_{H} is the winding hottest-spot temperature, ° C.
θ_{HR} is the rated winding hottest-spot temperature, ° C.

Equation (2) may be used to calculate equivalent ageing of the transformer (F_{EQA}):

$${F}_{EQA} = \frac{{\sum }_{n = 1}^{N} {F}_{AA} Δ {t}_{n}}{{\sum }_{n = 1}^{N} Δ {t}_{n}} \qquad Eq . 2$$

Where:
tₙ is time interval, h

The remaining service lifetime in hours can be calculated using equation 3:

$$Remaining service lifetime = Normal Insulation Life - {F}_{EQA} * operation time \qquad Eq . 3$$

On the other hand, the IEC standard loading guide is applicable mainly for the non-thermally upgraded paper, and the hot-spot temperature is limited to 98° C. at 20° C. ambient temperature.

The ageing rate given by the IEC model is mentioned in equation 4:

$$Ageing rate = {2}^{( {θ}_{H} - 98 ) / 6} \qquad Eq . 4$$

In practice, the above IEEE and IEC approaches to determining loss of life and remaining service lifetime generally have two stages. In the first stage, ambient temperature and load factor are taken as input parameters. In the second stage, the loss of life is calculated using the hot-spot temperatures computed by running the thermal models taking transformer parameters and real-time electrical data (for example, voltage, current, and/or power at the transformer). The most common thermal model used for oil and hot spot temperature calculations is described in the above indicated IEC-354 loading guide for oil-immersed transformers. For example, the steady-state temperature relations are given in the above IEC-354 loading guide. The ultimate hot spot temperature for a transformer under any load equals the sum of the ambient temperature, the oil temperature rise over ambient, and the hot spot temperature rise over oil. Note that the oil temperature in this case is typically measured as a top oil temperature as this is where a maintenance engineer will sample the oil. This can be expressed by the equation 5 below:

$${θ}_{H} = {θ}_{A} + Δ {θ}_{TO} + Δ {θ}_{H} \qquad Eq . 5$$

Where:
θ_{A} is the average ambient temperature during the load cycle to be studied, ° C.
θ_{TO} is the top-oil temperature, ° C.

The terms in equation 5 are well known to the skilled person and defined in the IEC-354 loading guide for oil-immersed transformers, and in the IEEE C57.91 standard, for example in Annex G thereof. Methods of measuring the physical parameters for and calculating the terms of equation 5 are also known to the skilled person. For example, measuring top oil temperature using a sampling dip-stick and identifying physical and structural parameters of the transformer being tested by referring to manufacturer datasheets and to metal nameplates affixed to the transformer on which this information is also recorded.

One example set of standard thermal models from IEEE standard C57.91 widely used with transformers is set out below for ease of reference.

Specifically, annex G of the IEEE standard C57.91 describes methods to estimate a transformer's hottest spot temperature given ambient temperatures and loading profiles. The transformer temperature model estimates the internal transformer temperatures using the Alternative Temperature Calculation method proposed in Annex G of the IEEE guide. The transformer temperature model uses forward Euler integration to estimate the internal transformer temperatures at one-minute intervals. As described above, transformer ageing results from transformer insulation break-down, which is directly related to the temperature of the transformer windings. Therefore, the winding's hottest spot temperatures, estimated by this model, are needed to determine the equivalent ageing of the transformer. The equations in annex G of the IEEE guide consider type of liquid, cooling mode, winding duct oil temperature rise, power losses due to harmonics, resistance and viscosity changes, ambient temperature, and load changes during a load cycle. The transformer temperature model uses the IEEE guide outlined below to estimate the winding hottest spot temperatures at each time interval. The overall model is based on the fluid flow conditions occurring in the transformer during transient conditions. The hottest-spot temperature comprises the following components as given in equation 6:

$${θ}_{H} = {θ}_{A} + Δ {θ}_{BO} + Δ {θ}_{H / WO} + {Δθ}_{WO / BO} \qquad Eq . 6$$

Where:
θ_{A} is the average ambient temperature during the load cycle to be studied, ° C.
Δθ_{BO} is the bottom fluid rise over ambient, ° C.
Δθ_{WO/BO} is the temperature rise of oil at winding hot-spot location over bottom oil, ° C.
Δθ_{H/WO} is the winding hot-spot temperature rise over oil next to hot-spot location, ° C.

The overall model is based on three separate, widely used, standard thermal models:
(i) Average oil temperature calculation
(ii) Average winding temperature calculations
(iii) Winding hottest spot temperature calculation.

These IEEE standard models precisely describe the heat transfer and fluid flow phenomena occurring in an oil-immersed transformer during transient loading.

For the first model, the average oil temperature calculation for a given transformer may be computed by evaluating equations 7-9:

$${Q}_{LOST , W} + {Q}_{C} + {Q}_{S} = {Q}_{ABS , AO} + {Q}_{LOST , O} \qquad Eq . 7$$

$${Q}_{ABS , AO} = ( \sum {MC}_{P} ) ( {θ}_{AO} [ k + 1 ] - {θ}_{AO} [ k ] ) \qquad Eq . 8$$

$$\sum {MC}_{P} = {M}_{Tank} {C}_{{P}_{Tank}} + {M}_{Core} {C}_{{P}_{Core}} + {M}_{Oil} {C}_{{P}_{Oil}} \qquad Eq . 9$$

Where:
Q_{LOST,W} is the heat lost by winding, W-min
Q_{C} is the heat generated by core, W-min
Q_{S} is the heat generated by stray losses, W-min
Q_{ABS,AO} is the heat absorbed by average fluid temperature, W-min
Q_{LOST,O} is the heat lost by fluid to ambient, W-min
MC_{P} is the mass times specific heat of fluid, tank, and core, W-min/° C.
M_{Tank} is the mass of tank, lb
C_{P}_{_{Tank}} is the specific heat of tank, W-min/lb° C.
M_{Core} is the mass of core, lb
C_{P}_{_{Core}} is the specific heat of core, W-min/lb° C.
Mₒᵢₗ is the mass of fluid, lb
C_{P}_{ₒᵢₗ} is the specific heat of fluid, W-min/lb° C.

For the second model, the average winding temperature calculation for a given transformer may be calculated by evaluating equations 10-11:

$${Q}_{GEN , W} = {Q}_{ABS , W} + {Q}_{LOST , W} \qquad Eq . 10$$

$${Q}_{ABS , W} = {M}_{W} {C}_{{P}_{W}} ( {θ}_{W} [ k + 1 ] - {θ}_{W} [ k ] ) \qquad Eq . 11$$

Where:
Q_{GEN,W} is the heat generated by windings, W-min
Q_{ABS,W} is the heat absorbed by winding, W-min
Q_{LOST,W} is the heat lost by winding, W-min
C_{P}_{_{W}} is the specific heat of winding, W-min/lb° C.
M_{W} is the mass of winding, lb
θ_{W} is the winding temperature, ° C.
k is the discrete timestep

For the third model, the winding hottest spot (i.e. a hot-spot) temperature calculation for a transformer may be computed by evaluating equations 12-13:

$${Q}_{GEN , HS} = {Q}_{ABS , HS} + {Q}_{LOST , HS} \qquad Eq . 12$$

$${Q}_{ABS , HS} = {M}_{W} {C}_{{P}_{W}} ( {θ}_{H} [ k + 1 ] - {θ}_{H} [ k ] ) \qquad Eq . 13$$

Where:
Q_{GEN,HS} is the heat generated at hot spot temperature, W-min
Q_{ABS,HS} is the heat absorbed at hot spot temperature, W-min
Q_{LOST,HS} is the heat lost at hot spot temperature, W-min

As described above, these IEEE standard equations are well known to the skilled person and allow a winding hotspot temperatures of a transformer to be estimated from simple temperature measurements in combination with a given transformer's physical, manufacturer parameters taken from data sheets and/or from nameplates affixed to a given transformer.

EP3061107 proposes a method for determining a reduction of remaining service lifetime of an electrical device from measured electrical and physical (e.g. temperature and humidity) to define a present, actual state of the transformer at a given time (e.g. what the accelerated aging rate is based on the present, actual state). This is then used to estimate how much the transformer is likely to have aged based on already and can be used to estimate the lifetime remaining. Thus, if the present, actual temperature and electrical measurement values indicate a transformer is currently under severe load, then the method of EP3061107 will return a conclusion that the remaining lifetime of the transformer is likely to be low. Conversely, if the present, actual measured values indicate the transformer is not under a severe load, the remaining lifetime is likely to be higher and need not be replaced as soon. However, the presently measured, actual values provide no indication of what load the transformer was under in the past. Further, this information cannot be determined from past data in the case of old transformers from the 1950s and 1960s because such data was never collected and thus does not exist.

An improved method of monitoring transformers of power networks is desired.

### SUMMARY

In general terms, the present disclosure solves these and other problems by simulating historical transformer load data from historical ambient environmental temperature data and historical energy consumption data of different geographic regions, and using this simulated historical data to calculate a more accurate remaining lifetime of the transformer. The methods of the present disclosure are a substantial improvement over the method of EP3061107 which does not, and is unable to, take into account the historical load of the transformer when making remaining lifetime calculations.

Specifically, the term historical load refers to the apparent power of a transformer over a historical time period. This is apparent power is indicative of the historical temperature (e.g. hotspot temperature) over time that the transformer has been operating at, which in turn is indicative of how much of the original service lifetime of the transformer has been used up. Thus, the present disclosure is directed to the following three main aspects: estimating historical apparent power over time of a transformer, estimating a historical temperature over that time of the transformer, and calculating a remaining service lifetime of the transformer using these estimates.

The historical apparent power over time is estimated by generating simulated data with a trained neural network to fill in any gaps in this data where it is not available, which is a particularly acute problem with older transformers from the 1950s and 1960s. Specifically, as long as at least some apparent power over time data can be obtained for a given set of geographical region, it is possible to predict what the apparent power over time data would be in these regions where the real data is incomplete or missing.

More specifically, the neural network is trained on data comprising apparent power data of a number of transformer devices in different geographic regions where this data is available, the ambient environmental temperature data over the time period for these regions, and the energy consumption data of a corresponding power network in these regions, for example obtained from historical state or national archives. The inventors have found that the ambient environmental temperature data and energy consumption data for a region over a time period are good indicators of what the apparent power of transformers in the region would have been during these time periods. This is advantageous because ambient environmental temperature data and regional energy consumption data are typically more widely available as they are collected by national state archives. Accordingly, a neural network can be trained to output this simulated apparent power data from these far more widely available inputs.

In turn, this simulated apparent power data can be used to provide a far more accurate estimate of remaining service lifetime of a given transformer. Which helps power network providers better manage the maintenance of their power networks.

According to a first aspect, there is provided a method of estimating historical apparent power over time of at least one transformer device in a power network in a geographic region, the method comprising: providing training data comprising: apparent power data of a plurality of transformer devices over time in one or more geographic regions, energy consumption data over time of the power network in the respective geographic regions, and ambient environmental temperature data over time of the respective geographic regions; initialising weights of an untrained neural network comprising an input layer, a plurality of hidden layers, and an output layer, and using the training data to iteratively update the weights to minimise a loss function to produce a trained neural network configured to output an estimated apparent power of a transformer device over a time period in a geographic region from input energy consumption data and input ambient environmental temperature data of said geographic region over said time period; and inputting energy consumption data and ambient environmental temperature data over a first time period in a geographic region into the trained neural network to estimate an apparent power over the first time period of at least one transformer device in the geographic region.

Optionally, the training data further comprises voltage harmonics data of said plurality of transformer devices.

According to a second aspect, there is provided a method of estimating a historical temperature over time of a transformer device in a power network in a geographic region, the method comprising: estimating a historical apparent power of the transformer device over a first time period with the above method; and estimating a historical temperature of the transformer device over the first time period with: (i) the estimated historical apparent power over the first time period, and (ii) with ambient environmental temperature data of the first time period in the geographic region.

Optionally, the temperature of the transformer device over the first time period comprises a maximum temperature present in one or more coil windings of the transformer device.

Optionally, the maximum temperature present in the one or more coil windings of the transformer device is calculated according to IEEE Standard C57.91.

According to a third aspect, there is provided a method of managing a power network having a plurality of transformer devices in respective geographic regions, the method comprising: estimating a remaining service lifetime of each transformer device by: estimating a historical apparent power of the transformer device over a first time period with the above methods; estimating a historical temperature of the transformer device over the first time period with the above methods; and calculating a remaining service lifetime of the transformer device by performing a loss of life calculation using the estimated historical apparent power and the estimated historical temperature over the first time period, and subtracting a result of the loss of life calculation from a predetermined maximum service life-time of the transformer device, and generating a warning when a calculated remaining service lifetime of any of the plurality of transformer devices falls below a predetermined threshold.

Optionally, the loss of life calculation comprises a loss of life calculation according to an ANSI/IEEEC57.91 and IEC-354.91 standard.

Optionally, said calculating the remaining lifetime of the transformer device by performing the loss of life calculation further comprises using a real-time measurement of the apparent power and a real-time measurement of the temperature of the transformer device.

Optionally, said real-time measurement of the apparent power of the transformer device comprises performing a real-time measurement of one or more of cur-rent, voltage and/or power at a connection of the transformer device to the power network.

Optionally, the real-time measurement of the temperature of the transformer device comprises measuring an outside surface of a housing of transformer device without opening said housing.

Optionally, the method comprising continuously performing said real-time measurements.

Optionally, said predetermined maximum service lifetime of the transformer device is between 30 and 60 years.

According to a fourth aspect, there is provided a system for managing a power network, the system comprising: a processor; and a plurality of transformer devices in respective geographic regions, each transformer device communicatively coupled to the server and configured to send data indicative of a real-time apparent power measurement and a real-time temperature measurement of the transformer device to the server, wherein the processor is configured to perform the steps of: for each transformer device, input into a trained neural network: (i) the received real-time data, and (ii) historical power consumption data and historical ambient environmental temperature data of the corresponding geographic region of the transformer device from a first period of time collected before said real-time measurements, the trained neural network being configured to output an estimated historical apparent power of the transformer device over the first period time, with the real-time apparent power measurement and the historical apparent power estimate, calculate a remaining service lifetime of the transformer device, and generate a warning when the calculated remaining service lifetime of transformer devices falls below a predetermined threshold.

Optionally, the processor is configured to perform said steps at least once a day, or at even smaller intervals for example, once every 10 minutes, or once every 1 minute.

Optionally, the system comprises a user interface for displaying the geographic regions and locations of the plurality of transformer devices on a map, wherein the user interface is configured to display the warning.

Optionally, at least one of the plurality of transformer devices comprises an oil-immersed transformer device.

According to a fifth aspect, there is provided a method of training a neural network to output an estimated apparent power of a transformer device over a time period in a geographic region from input energy consumption data and input ambient environmental temperature data of said geographic region over said time period, the method comprising: providing training data comprising: apparent power data of a plurality of transformer devices over time in one or more geographic regions, energy consumption data over time of the power network in the respective geographic regions, and ambient environmental temperature data over time of the respective geographic regions; initialising weights of an untrained neural network comprising an input layer, a plurality of hidden layers, and an output layer, and using the training data to iteratively update the weights to minimise a loss function to produce a trained neural network configured to output an estimated apparent power of a transformer device over a time period in a geographic region from input energy consumption data and input ambient environmental temperature data of said geographic region over said time period.

### BRIEF DESCRIPTION OF THE DRAWINGS

These and other aspects will now be described by reference to the drawings in which:

FIG. 1 illustratively shows a block diagram according to the present disclosure

### DETAILED DESCRIPTION

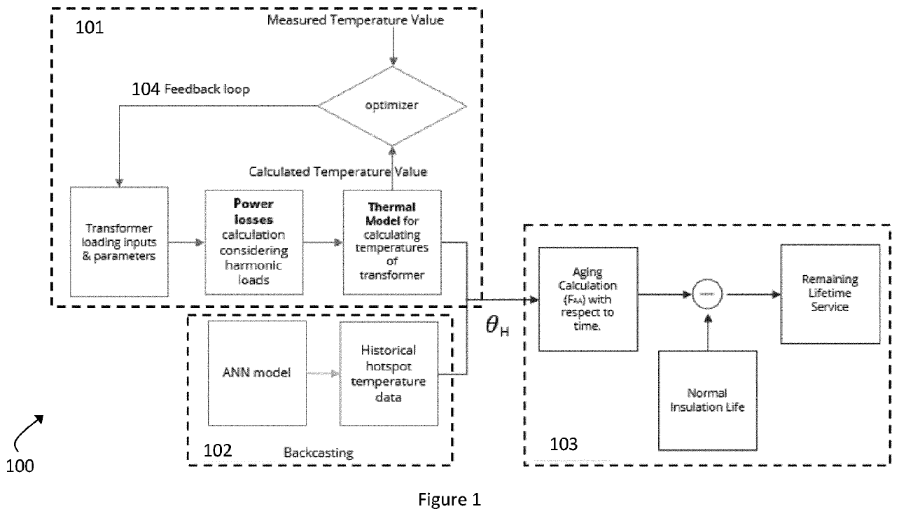

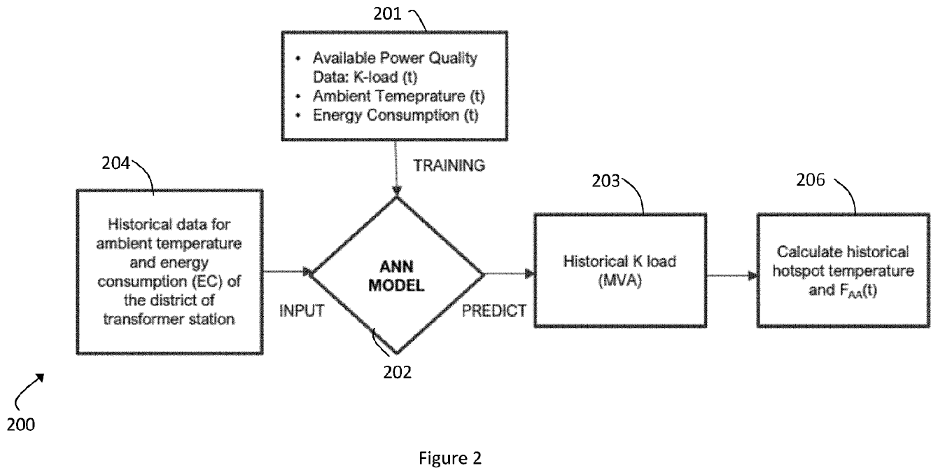

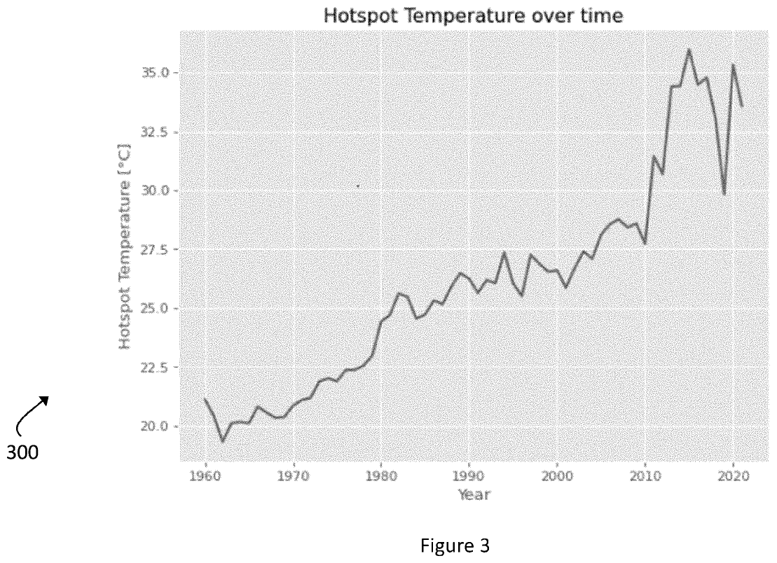

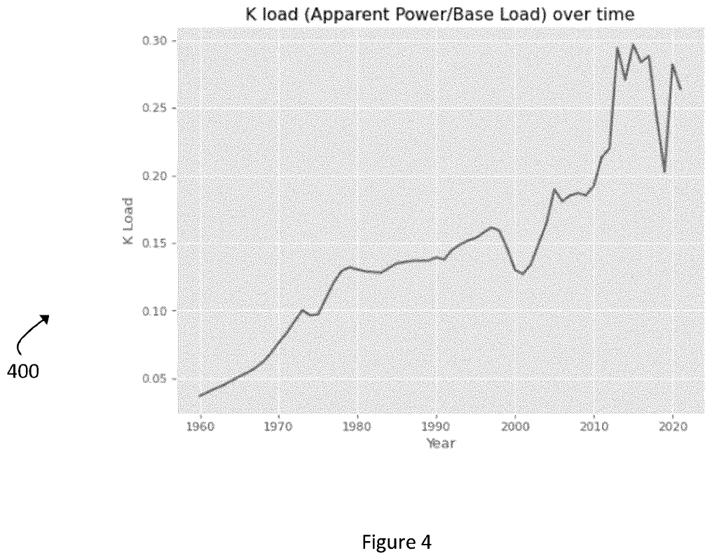

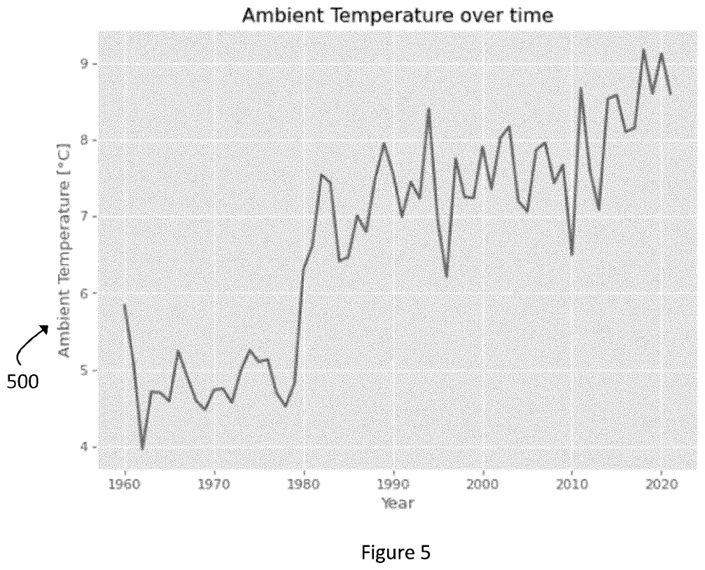

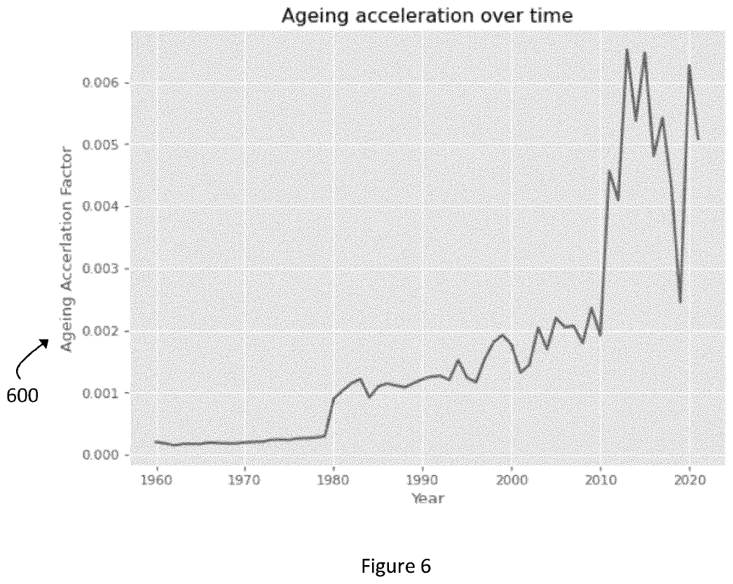

FIG. 1 illustratively shows a block diagram 100 according to the present disclosure. The block diagram 100 has a first section 101, a second section 102 and a third section 103.

The first section 101 concerns calculating winding hotspot temperatures from real-time power quality data. In the illustrative example of FIG. 1, this consists of applying the three thermal models described above in connection with the widely used IEEE standard are applied, an evaluation of spot temperature is performed, and an optimising function for refinement of transformer physical parameters is performed. It is envisaged that the presently described method of calculating hotspot temperatures is illustrative only and not intending to be limiting, and the skilled person is aware of other methods of calculating and measuring hotspot temperatures.

The second section 102 concerns estimating hotspot temperatures for the historical load of the transformer. As described above, historical transformer data is typically not available or largely incomplete for many transformers, particularly those installed during the 1950s and 1960s, so a neural network is provided that receives the energy consumption and the ambient temperature along with the day and time to back ast the loading on the transformer for any period of missing data. It is trained using the real-time power quality data gathered along any recorded period to predict the historical load.

The third section 103 concerns calculating the remaining lifetime using the well-known IEEE standard equations (1)-(3), described above. Although it is envisaged that other known equations capable of calculating remaining lifetime may also be used, and that the specific equations used to calculate remaining lifetime are illustrative only and not intending to be limiting.

### First Section 101

### Hotspot Temperature Calculation on Real-Time Power Quality Data

As described above, transformers are typically manufactured and rated by the manufacturer with a number of main operating and physical parameters, for example those shown in the list below:

### Size (KVA)

Year of manufacture
Mass of windings kg
Mass of core kg
Weight of transformer without fluid kg
Mass of tank kg

### Transformer Type

Cooling method (ONON, ONAF, OFAF, ODAF)
Cooling/insulation fluid type (oil, silicone, or HTAC)17
Winding material (Copper or aluminium)

### Losses

Winding I2R losses W
Winding eddy current losses W
Core (no-load) losses W
Stray losses, if any. W
Eddy's current losses at winding hot spot location per unit of 12R losses 1
Current at rated load (LV) A

### Masses and Volumes

Total weight of the transformer kg
Weight of transformer fluid kg
Weight of core and coil kg

### Temperatures (Measured at Rated Load P_BASE_LOAD)

Baseload of the transformer kW
Rated ambient temperature° C.
The average winding temperature at the rated load ° C.
Winding hottest spot temperature at rated load ° C.
The top fluid temperature at the rated load ° C.
The bottom fluid temperature at the rated load ° C.

### Parameters for Ageing Equation

Normal insulation life (approximately 20 years) s

### Miscellaneous

Winding time constant s
Per unit of winding height to hot spot location 1
Constant in exponential moving average filter for Theta_DAO 1
Constant in exponential moving average filter for Theta_TDO 1

These parameters, typically recorded on a nameplate affixed to the transformer by the original manufacturer and/or provided in manufacturer datasheets, together with real-time power quality measurements from the transformer, may be used to calculate a theoretical power loss of each transformer in a power network (which is lost as heat for example caused by the transformer's real-time voltage and current harmonics which influence hotspot temperature of the transformer).

To obtain the real-time power quality measurements, one or more sensor devices installed on each transformer in a power network may be configured to collect the following real-time data:
Voltage and current harmonics up to, for example, the 15th multiple of the fundamental frequency
Active power
Reactive power
Voltage
Current
Frequency
Power factor

It is known that an increase in harmonic distortions can result in a corresponding decrease in the expected life of the transformer. Thus, considering harmonics in the calculations is beneficial to accurately determining the electrical device's current state.

As mentioned before, non-linear loads in most power networks around the globe have increased, which results in distorted voltage and current waveforms. This contributes to deteriorating the quality of electricity flowing in the network. It has a direct impact on the transformer's operation. A transformer is a source of energy loss during its operation. The types of power losses effected by harmonics include: transformer losses, no load losses, load losses (P_{LL}), ohmic losses (P_{I2R}), stray losses (P_{OSL}), winding eddy current losses (P_{EC}) and others.

The no-load losses, also known as the core losses, appear because of the time-variable nature of electromagnetic flux passing through the core that is caused due to the history of the hysteresis phenomenon and eddy currents in the magnetic body. They consider the frequency and maximum flux density. The load losses include ohmic losses, losses in windings and other stray losses. Ohmic losses amount by increasing winding DC resistance and load current. It also considers the harmonic component. The electromagnetic force's skin and proximity effects cover the winding and give rise to eddy current losses.

Due to the linkage between the electromagnetic flux and conductor, the voltage induced in the conductor produces an eddy current and increases the windings' temperature. Eddy current loss, produced in structural parts of the transformer except for the winding, is considered under stray losses. In a heavily loaded transformer with harmonic currents, the excess loss can cause a high temperature at some locations in the windings. This can seriously reduce the life span of the transformer and even cause immediate damage and sometimes fire. Reducing the maximum apparent power transferred by the transformer is often called de-rating

A known formula for calculating loss with harmonics is given in the following equations 14-17:

$${P}_{LL} = {P}_{{I}^{2} R} + {P}_{EC} + {P}_{OSL} \qquad Eq . 14$$

$${P}_{{I}^{2} R} = {R}_{DC} {\sum }_{h = 1}^{{h}_{max}} {I}_{{h}^{2}} \qquad Eq . 15$$

$${P}_{EC} = {R}_{EC - R} {\sum }_{h = 1}^{{h}_{max}} {( \frac{{I}_{h}}{{I}_{R}} )}^{2} {h}^{2} \qquad Eq . 16$$

$${P}_{OSL} = {R}_{OSL - R} {\sum }_{h = 1}^{{h}_{max}} {( \frac{{I}_{h}}{{I}_{R}} )}^{2} {h}^{0.8} \qquad Eq . 17$$

Where:
P_{OSL-R} is the other stray loss under rated conditions, W
P_{LL} is the load loss, W
P_{I}_{²}_{R} is the I²R loss portion of the load loss, W
P_{EC} is the winding eddy-current loss, W
P_{OSL} is the other stray loss, W
P_{EC-R} is the winding eddy-current loss under rated conditions, W
P_{HS} is the winding I²R loss at rated load and rated hot-spot temperature, W
P_{EHS} is the eddy loss of windings at rated load and rated winding hot-spot temperature, W
h is the harmonic order
Iₕ is the rms current at harmonic “h” (amperes)
I_{R} is the rms fundamental current under rated frequency and rated load conditions, A
R_{DC} is the de resistance,

### Thermal Model

It is envisaged that the three thermal models from the IEEE standard for calculating the three primary temperatures of transformers (equations 6-13 as discussed above in the background section) may be used to estimate hotspot temperature twice. Firstly, a theoretical hotspot temperature based on the manufacturer parameters taken from datasheets and/or nameplates affixed to the transformer, and secondly based on an actual measurement based on a top oil temperature estimate taken by measuring an outside surface of a transformer housing using e.g. a thermocouple or IR sensor.

As described above, equations 6-13 take into account factors include the type of liquid, cooling modes, winding duct oil temperature rise, viscosity changes, ambient temperature, and the load changes during a load cycle. As will be appreciated, the hotspot estimate contributes significantly to the loss calculation, whereby power losses due to harmonics are in some cases the foremost reason for the increase in the hotspot temperature. Since, in most apparatus, the temperature distribution is not uniform, the part operating at the highest temperature will ordinarily undergo the most significant deterioration. Therefore, it is usual to consider the ageing effects produced by the highest (hottest spot) temperature in transformer ageing estimations. Using the losses calculated considering the harmonics in the grid and the temperature calculations set by IEEE methods described above, the hotspot temperature can be calculated for a given time. It will be appreciated that other methods of estimating hotspot temperature of a transformer are also known to the skilled person.

### Optimiser

The reason two separate estimates of hot spot temperature is made is so that the transformer operating parameters can be adjusted to take into account degradation and/or imperfections in the manufacturer given details. That is, if the hot spot temperature estimation based on the measured values is substantially different to that based on the theoretical manufacturer values then the theoretical manufacturer values are likely to be incorrect and/or out of date and accordingly need to be adjusted to match the actual measured temperature value more closely. This optimisation process is indicated by feedback loop 104.

Specifically, as described above, a transformer, like all other electrical equipment, is designed and manufactured to function in an electrical system at a specified voltage, frequency, load, etc. These main operating parameters change due to excessive heat, fluctuating ambient temperatures, or difficulty in cooling. Hence, the exact parameter values used for inputting into the IEEE thermal models must be recalculated regularly to compensate for these changes.

The parameters used in temperature calculation methods must be recalculated to reflect the current state of the transformer. SLSQP (Sequential Least SQuares Programming optimizer) is used to optimize the set of parameters by minimizing a set of objective functions. The difference between the calculated, theoretical top oil temperature and the measured or estimated top oil temperature can be used as the objective function to optimize the transformer parameters according to the current operational state.

However, as described above, sampling oil temperature would be an intrusive method.

Instead, as describe above in order to calculate hotspot temperature for a given transformer, a temperature sensor such as a thermocouple probe and/or IR sensor may be installed on an outside surface of the transformer housing, for example on an outside surface of the tank in which the oil-immersed transformer is housed. Specifically, the temperature of the tank's surface is easily measurable using temperature sensors, such as thermocouple probes, without accessing a transformer internally. If the top oil temperature can be estimated using the tank surface temperature, the IEEE loading guide winding hot spot temperature model referred to above can be applied better than when only the ambient temperature is used. This estimation can then be used to estimate winding temperature using the IEEE loading guide model. The relation between the top oil and the tank surface of a transformer is given below:

$${θ}_{TO} = α \cdot {θ}_{TS} + β$$

This equation effectively defines a linear relationship between coil winding temperature θ_{TO} and tank surface θ_{TS} temperature with slope a and offset β dependent on the general structure and specifications of a transformer (for example, number of windings, oil tank size, and so on). In other words, the hotter coil winding temperature, the hotter the oil tank surface. The exact values of a and offset β can be determined in a controlled environment for each type of transformer in a power network and then later used to allow coil winding temperature to be easily estimated in real-time solely from a temperature reading of the oil tank surface of each type of transformer of a power network.

### Second Section 102

### Hotspot Temperature Calculation for Historical Load

As described above, known methods do not and are not able to take into account historical load data (and any hotspot temperatures calculated therefrom) because this data is largely incomplete or wholly unavailable in many geographic regions.

This historical load profile is also known as the K load. Historical load data for the lifetime of a transformer is a largely incomplete dataset. Many transformers currently in operation were installed during the 1950s and 1960s. Utility companies did not have the technology to collect and store the necessary power quality data for the temperature calculations according to the current state of the thermal model, such as the IEEE standard for oil-filled transformers in the electricity grid.

Instead, the present disclosure envisages overcoming this problem by generating a simulated historical load profile for geographic regions where this data is not available. For modelling the historical load profile, a neural network model capable of predicting the apparent power (K load×constant baseload) was trained based on the inputs: the energy consumption, ambient temperature, and calendrical features such as year, month, weekday/weekend, and time of the day. The training data is composed of three data sources: the transformer's active power and reactive power, the energy consumption of the district at which the transformer is stationed, and the ambient temperatures of that region. These data sources need not be available for all periods of time going back to the 1950s and 1960s or indeed for all geographic regions, as long as at least some training data is available, the model can be successfully trained to generalise to almost any time period and geographic region. Thus, the model trained from this data source was used to predict the historical apparent power based on the historical ambient temperature and energy consumption.

FIG. 2 illustratively shows a block diagram 200 according to the present disclosure illustrating the generation of the simulated historical load data. In a first step, a training data set 201 is provided that comprises any power quality data i.e. K-load data, ambient temperature data, and energy consumption data that is available for a given time period t. This data may be divided based on geographic regions. This is advantageous because ambient temperature data is typically recorded by national weather services by geographic region down to the level of town, province, state, and so on, which is similar to the regions for which energy consumption data is recorded by governmental organisations. This division of data by geographic region also makes it easy to group transformers in a power network into one or more regions, based on where they are physically located.

Weights and biases of an untrained neural network are then initialised and iteratively updated during training to minimise a loss function to produce a trained neural network 202.

It will be appreciated that any suitable artificial neural network (ANN) architecture may be used. For example, a suitable number of layers of neurons (e.g. number of input, output, hidden layers), the number of neurons per layer, their connections to each other, their activation functions, for example a ReLU function, what loss function and optimising method is used, what learning rate, batch size, and regularisation parameters are used for training the network, and so on. It will further be appreciated that the skilled person may adjust any of these parameters during training to achieve an acceptable loss curve and convergence during training on a given training data set. Example architectures envisaged may include a recurrent neural network (RNN) or long short-term memory (LSTM) approach.

Once the network 202 has been trained on the training data set 201, it is able to output a predicted historical K-load profile 203 for a given time period from input historical data for ambient temperature and energy consumption 204 over that time period which is a good estimated simulation of the historical K-load 203 of any transformers falling within a geographic region from which the input ambient temperature and energy consumption data was taken.

The output historical K-load data for the time period and geographic region may then be used to calculate corresponding historical hotspot data for that time period and region, which is thus a good estimate of hotspot temperatures over time for any transformers in that geographic region. The hotspot data may be calculated from the K-load data in combination with the ambient temperature data for the given time period using the equations 7-13, for example. It will be appreciated that the skilled person will understand that other methods of calculating a hotspot from apparent power (i.e. K-load data) may also be used, for example any methods also described in the above-mentioned IEEE standards or other stands. By generating simulated load and hotspot data in this way, the problem of missing or incomplete historical datasets is overcome and the contribution to ageing that historical load had the transformer is thereby taken into account. This is an improvement over methods such as those provided by EP3061107, which do not and are not able to take into account historical data, as this data is typically incomplete or does not exist.

Finally, with the estimated historical hotspot data, the remaining life time FAA value may be calculated for every time point from the historical data, and the real-time actual/measured data where present, using equation 1. This accordingly provides a good understanding of how much a given transformer has actually aged over the operational time period and accordingly is a better indication of whether or not replacement is likely.

### EXAMPLES

The inventors have demonstrated the efficacy of the above method as is set out below.

Data from an example transformer (500MVA and 230/110 KV) was recorded. The transformer had been operating from 1960-2022 and the theoretical i.e. rated hotspot temperature based on the manufacturer information for this transformer at this point in its lifetime should be 85° C. This theoretical hotspot estimation would normally indicate that this transformer is likely to be reaching the end of its lifetime and accordingly due to be replaced.

FIG. 3 shows a chart 300 of estimated hotspot temperature over time of the operational period of the transformer (i.e. from 1960-2022) generated using the method of the present disclosure, i.e. generated by a trained neural network from input energy consumption and ambient environment temperature data of the geographic region in which the transformer was located.

The x-axis is the overall time the transformer has been in operation, and the y-axis depicts the hotspot temperature in ° C. It can be seen that the hotspot temperature has increased since 1960. However, the range of the hotspot temperature stays between 20° C. to 35° C., which is substantially lower than the theoretical hotspot estimate based solely on the manufacturer's data. From this chart, it can be inferred that the top oil of the transformer does not heat up a lot and accordingly that the cooling of the oil is in an excellent working state.

FIG. 4 shows a chart 400 of estimated K-load (apparent power/base load) over time of the example transformer described above. As before, the load profile of the transformer is presented during its operational time of 1960-2022. As can be seen in FIG. 4, the x-axis shows the K-load increasing over time but not significantly so.

FIG. 5 shows a chart 500 of ambient temperature data over time for the geographic region in which example transformer above is located, and for the time period of 1960-2022. It can be inferred that the hotspot temperature increases in parallel to the loading on the transformer and that ambient temperature also plays a part in affecting the hotspot temperature. The ambient temperature of the geographic location is relatively low between 4 and 9° C. and in fact this helps with the cooling of the transformer. Hence, it can be seen that the hotspot temperature is substantially lower than its manufacturer data rated value throughout its operational time. No significant rise in temperature has occurred for the transformer.

FIG. 6 shows a chart of average ageing acceleration factor FAA over time for the example transformer above calculated using the hotspot temperature data of FIG. 3. For example, as follows:

$$Normal lifetime = 50 years$$

$$Operational time = 61.9986 years$$

$$Equivalent {F}_{AA} = 0.00188$$

$$Ageing = Operational time \times Equivalent {F}_{AA} = 0.1163 years$$

$$Remaining lifetime = Normal lifetime - Ageing = 49.8837 years$$

The remaining lifetime of the transformer was calculated to be approximately another 49.8 years which is in addition to its already normal lifetime of 50 years. Thus, if the transformer operates under similar conditions it has operated under since 1960, it will likely have double the service lifetime it was originally intended to have. Thus, the transformer is in good condition, and the power network provider can keep the transformer running for more time.

Thus, the graph in FIG. 6 shows that the FAA value, although increasing, stays on average generally within the limit of 0.002 and 0.004. The example transformer thus has a much slower than linear ageing, as seen from the FAA factor. If the transformer's hotspot temperature stays under the rated hotspot temperature throughout its operational time, it can be concluded that less power losses occur, and the transformer is under-loaded. Hence, the transformer will last longer than the expected lifetime and the power network does not need to replace it imminently. This is the opposite conclusion than that which would have been reached had the power network provider relied solely on the manufacturer rated information for a transformer that has operated since 1960.

The present disclosure thus provides an effective way at better prioritising which transformers in a power network need replacing and when.

In summary, transformers are one of the more expensive equipment's found in a power network provider's inventory. This leads to an increasing need for tools to support transformer protection and the intelligent monitoring of their status, activities, and history. A monitoring system itself provides only raw information, that without processing doesn't bring any additional value to the power network provider. The methods provided in this disclosure accordingly bring value for power network providers in the form of:
The remaining lifetime value provides information about the ageing of a transformer in power networks. This allows the power network provider to evaluate the status of the transformer and returns an overall lifetime value. Understanding the current state enables the utility to make better decisions on replacing transformers and, more importantly, helps them to prioritise replacements. This results directly in the reduction of capital and operational expenses.
The model can correctly estimate the hot-spot temperature and its associated average acceleration factor FAA. This information gives an indication to the power network providers as to how fast the transformer is ageing and can help them to plan their maintenance activities better. The output from the algorithm also gives indication of certain parameters such as requirement of oil change, reduction in loading capabilities or even ventilation supplies that supports the maintenance activities.
The power network provider can use methods of the present disclosure to assess the hotspot temperature and the average acceleration factor to support optimal operation for the transformers, for example by reducing the load on one or more transformers that are deemed to be in worse conditions than others, thus allowing the power network provider to better manage the network to make existing transformers last longer without needing replacement.
The present disclosure allows a power network provider to understand the ambient environmental temperature effect on the transformer and can help the power network provider decide on the geographic location for future transformer replacements.

1. A computer-implemented method of estimating historical apparent power over time of at least one transformer device in a power network in a geographic region, the method comprising:
providing training data comprising: active and reactive power data of a plurality of transformer devices over time in one or more geographic regions, energy consumption data over time of the power network in the respective geographic regions, and ambient environmental temperature data over time of the respective geographic regions;
initialising weights of an untrained neural network to iteratively update the weights to minimise a loss function to produce a trained neural network configured to output an estimated apparent power of a transformer device over a time period in a geographic region from input energy consumption data and input ambient environmental temperature data of said geographic region over said time period; and
inputting energy consumption data and ambient environmental temperature data over a first time period in a geographic region into the trained neural network to estimate an apparent power over the first time period of at least one transformer device in the geographic region.

2. The method of claim 1, wherein the training data further comprises voltage harmonics data of said plurality of transformer devices.

3. The method of claim 1, wherein the method is for estimating a historical temperature over time of a transformer device in a power network in a geographic region, and wherein the method comprises:
estimating a historical apparent power of the transformer device over a first time period with the method of claim 1; and
estimating a historical temperature of the transformer device over the first time period with: (i) the estimated historical apparent power over the first time period, and (ii) with ambient environmental temperature data of the first time period in the geographic region.

4. The method of claim 3, wherein the temperature of the transformer device over the first time period comprises a maximum temperature present in one or more coil windings of the transformer device.

5. The method of claim 4, wherein the maximum temperature present in the one or more coil windings of the transformer device is calculated according to IEEE Standard C57.91.

6. A method of managing a power network having a plurality of transformer devices in respective geographic regions, the method comprising:
estimating a remaining service lifetime of each transformer device by:
estimating a historical apparent power of the transformer device over a first time period with the method of claim 1;
estimating a historical temperature of the transformer device over the first time period with: (i) the estimated historical apparent power over the first time period, and (ii) with ambient environmental temperature data of the first time period in the geographic region; and
calculating a remaining service lifetime of the transformer device by performing a loss of life calculation using the estimated historical apparent power and the estimated historical temperature over the first time period, and subtracting a result of the loss of life calculation from a predetermined maximum service lifetime of the transformer device, and
generating a warning when a calculated remaining service lifetime of any of the plurality of transformer devices falls below a predetermined threshold.

7. The method of claim 6, wherein the loss of life calculation comprises a loss of life calculation according to an ANSI/IEEEC57.91 and IEC-354.91 standard.

8. The method of claim 6, wherein said calculating the remaining lifetime of the transformer device by performing the loss of life calculation further comprises using a real-time measurement of the apparent power and a real-time measurement of the temperature of the transformer device.

9. The method of claim 8, wherein said real-time measurement of the apparent power of the transformer device comprises performing a real-time measurement of one or more of current, voltage and/or power at a connection of the transformer device to the power network.

10. The method of claim 8, wherein the real-time measurement of the temperature of the transformer device comprises measuring an outside surface of a housing of transformer device without opening said housing.

11. The method of claim 8, comprising continuously performing said real-time measurements.

12. The method of claim 8, wherein the predetermined maximum service lifetime of the transformer device is between 30 and 60 years.

13. A system for managing a power network, the system comprising:
a processor; and
a plurality of transformer devices in respective geographic regions, each transformer device communicatively coupled to the server and configured to send data indicative of a real-time apparent power measurement and a real-time temperature measurement of the transformer device to the server,
wherein the processor is configured to perform the steps of:
for each transformer device, input into a trained neural network: (i) the received real-time data, and (ii) historical power consumption data and historical ambient environmental temperature data of the corresponding geographic region of the transformer device from a first period of time collected before said real-time measurements, the trained neural network being configured to output an estimated historical apparent power of the transformer device over the first period time,
with the real-time apparent power measurement and the historical apparent power estimate, calculate a remaining service lifetime of the transformer device, and
generate a warning when the calculated remaining service lifetime of transformer devices falls below a predetermined threshold.

14. The system of claim 13, wherein the processor is configured to perform said steps at least once a day.

15. The system of claim 13-er 14, comprising a user interface for displaying the geographic regions and locations of the plurality of transformer devices on a map, wherein the user interface is configured to display the warning.

16. The system of any of claim 13-15, wherein at least one of the plurality of transformer devices comprises an oil-immersed transformer device.

17. A computer-implemented method of training a neural network to output an estimated apparent power of a transformer device over a time period in a geographic region from input energy consumption data and input ambient environmental temperature data of said geographic region over said time period, the method comprising:
providing training data comprising: apparent power data of a plurality of transformer devices over time in one or more geographic regions, energy consumption data over time of the power network in the respective geographic regions, and ambient environmental temperature data over time of the respective geographic regions;
initialising weights of an untrained neural network comprising an input layer, a plurality of hidden layers, and an output layer, and using the training data to iteratively update the weights to minimise a loss function to produce a trained neural network configured to output an estimated apparent power of a transformer device over a time period in a geographic region from input energy consumption data and input ambient environmental temperature data of said geographic region over said time period.
